(19) United States
(12) Patent Application Publication
(10) Pub. No.: US 2024/0153957 A1
(43) Pub. Date: May 9, 2024

(54) SWITCH LNA MODULE

(71) Applicant: X-FAB France SAS, Corbeil-Essonnes (FR)

(72) Inventors: Ousmane SOW, Corbeil-Essonnes (FR); Imène LAHBIB, Corbeil-Essonnes (FR); Gregory U’REN, Corbeil-Essonnes (FR)

(21) Appl. No.: 18/387,945

(22) Filed: Nov. 8, 2023

(30) Foreign Application Priority Data
Nov. 8, 2022 (FR) 2211641
Dec. 9, 2022 (FR) 2213093
Jul. 25, 2023 (GB) 2311415.0

(51) Int. Cl. H01L 27/12; H01L 29/66; H03F 1/32; H03F 3/195

(52) U.S. Cl. CPC H01L 27/1207; H01L 29/6631; H03F 1/32; H03F 3/195; H03F 2200/294

(57) ABSTRACT

A switch LNA module including a silicon on insulator, SOI, wafer having a silicon substrate and an active layer separated by a buried oxide, BOX, layer, wherein the SOI substrate is a high resistance, HR, SOI substrate having a silicon handle wafer with a resistivity greater than 1 kΩ-cm. The switch LNA module further includes a switch having a plurality of SOI transistors, a low noise amplifier, LNA, located in the SOI wafer and connected to an output of the switch. The LNA includes a bipolar transistor formed in a bulk region of the SOI wafer where the BOX layer is removed. The switch LNA module further includes a thick metal layer for connecting to the switch and to the LNA.

This application claims priority to French Patent Application No. 2211641 filed on Nov. 8, 2022, and French Patent Application No. 2213093 filed on Dec. 9, 2022, and United Kingdom Application No. 2311415.0 filed on Jul. 25, 2023. The entire contents of each of these applications is hereby incorporated by reference.

The present disclosure concerns switch low noise amplifier (LNA) modules e.g. circuits comprising a switch with silicon on insulator (SOI) transistors and an LNA.

### BACKGROUND

New telecommunications technology requires new and improved devices on the semiconductor level. The new standard, 5G-NR can enable higher data rates (>100 Mbit/s, max of 20 Gbit/s), higher density (more connected equipment/km2), and lower latency (ideally from 10 to 1 ms).

For 5G, group III-V semiconductor technologies (e.g. GaAs) look promising, but have some downsides such as high power consumption, low quality factor passives, low integration level, difficulty to mass produce and high costs.

In silicon on insulator (SOI) technology circuitry is formed in a silicon layer that is isolated from the substrate by an electrically insulating layer. This has the advantage of reduced in parasitic capacitance which allows access to a more desirable power-speed performance horizon. Hence, SOI structures can be advantageous for high frequency applications such as radio frequency (RF) communication circuits.

### SUMMARY

Aspects of the disclosure provide a switch LNA module and an apparatus comprising such a module as set out in the appended claims.

Certain embodiments are described below with reference to the accompanying drawings.

### BRIEF DESCRIPTION OF DRAWINGS

FIG. 1 depicts a schematic diagram of a part of a telecommunications system, such as a user equipment (UE) or other apparatus for telecommunications, according to an embodiment;

FIG. 2 depicts a circuit diagram of a series/shunt single pole double throw (SPDT) switch comprising SOI transistors;

FIG. 3 depicts a schematic diagram of a switch;

FIG. 4 depicts the small and large signal plots of a switch;

FIG. 5 depicts a schematic diagram of a switch LNA module according to an embodiment comprising a two stage low noise amplifier (LNA), where the first stage is a SiGe based transistor while the second stage is a cascode comprising SiGe and SOI transistors;

FIG. 6 depicts the simulated small signal plots of the embodiment;

FIG. 7 depicts the simulated large signal plots of the embodiment;

FIG. 8 depicts a schematic diagram of a switch LNA module according to another embodiment comprising a single stage LNA comprising a cascode structure comprising two SiGe transistors in a bulk region of a SOI wafer;

FIG. 9 depicts a schematic diagram of a switch LNA module according to an embodiment comprising a single stage LNA comprising a cascode structure comprising one SiGe transistor and one SOI transistor;

FIG. 10 depicts a schematic diagram of a switch LNA module according to another embodiment comprising a two stage LNA comprising a SiGe transistor in the first stage and a cascode structure comprising two SOI transistors in the second stage;

FIG. 11 depicts a schematic cross-section of a part of a switch LNA module according to an embodiment; and

FIG. 12 depicts a schematic diagram of a part of a LNA illustrating the SOI wafer and the backend stack comprising metal layers.

### DETAILED DESCRIPTION

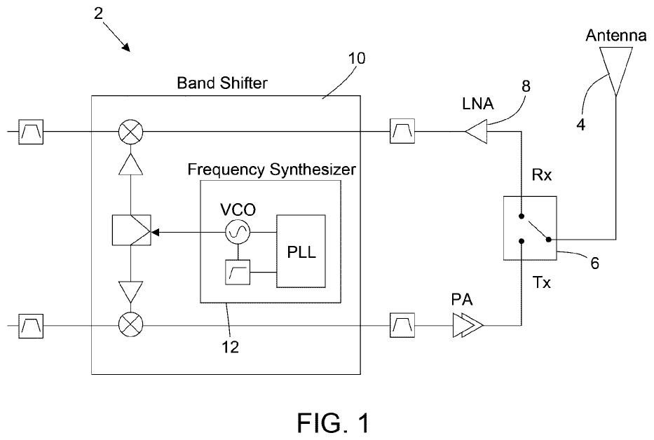

FIG. 1 shows a part of a telecommunications system 2 comprising an antenna 4 for transmitting and receiving electromagnetic signals, a switch 6 connected to the antenna for switching between transmission (Tx) and reception (Rx) modes, and a low noise amplifier (LNA) 8 for amplifying received signals from the antenna 4. The system further comprises a band shifter 10 for upshifting or downshifting signals, wherein the band shifter comprises a frequency synthesizer 12. The system 2 may be part of a node such as a base node in a 5G network for telecommunications, or a user equipment (UE) such as a mobile phone.

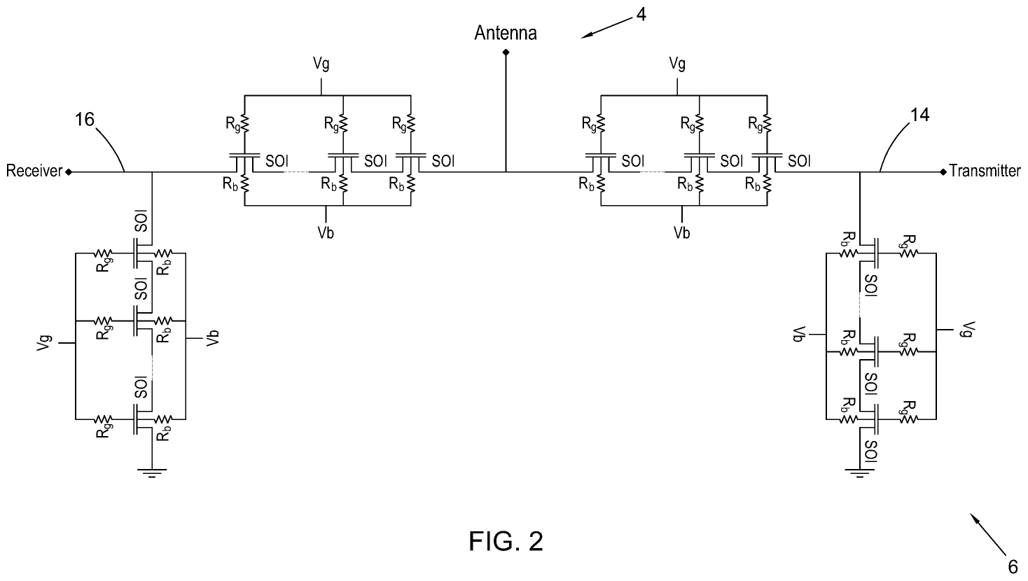

FIG. 2 shows a circuit diagram of a switch 6 according to an embodiment, which may be the switch 6 of the system illustrated in FIG. 1. The same reference numerals are used for similar or equivalent features in different figures to aid understanding, and are not intended to limit the illustrated embodiments. The switch 6 is connected to the antenna 4 and to a transmit path 14 for transmitting signals with the antenna 4 and a receiver path 16 for signals received with the antenna 4. The switch 6 comprises a plurality of SOI transistors (e.g. CMOS transistors formed on the SOI wafer). The switch comprises series/shunt stacked transistors. The SOI wafer may comprise a high resistance (HR) SOI substrate. For example, the SOI wafer may comprise a silicon handling wafer having a resistivity greater than 3 kΩ-cm.

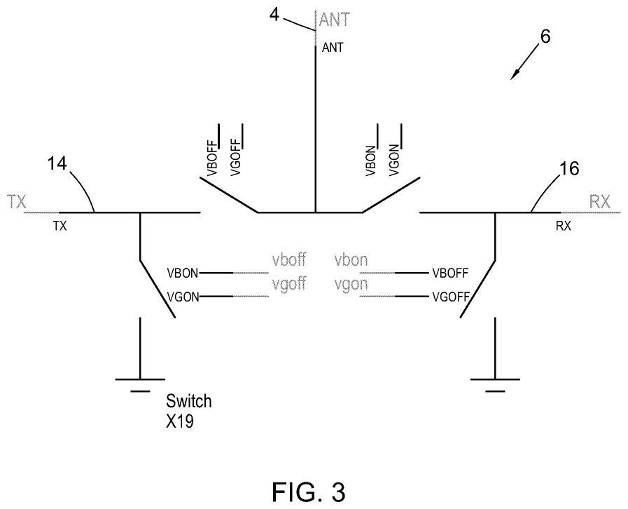

FIG. 3 shows a schematic circuit diagram of a switch 6 configured to switch an antenna 4 between a transmit path 14 and a receiver path 16 for operating in TX and RX modes respectively. The switch 6 is a semiconductor switch, operated by applying a voltage to different transistors in the switch. The switch 6 may be the switch illustrated in FIG. 1 and/or FIG. 2.

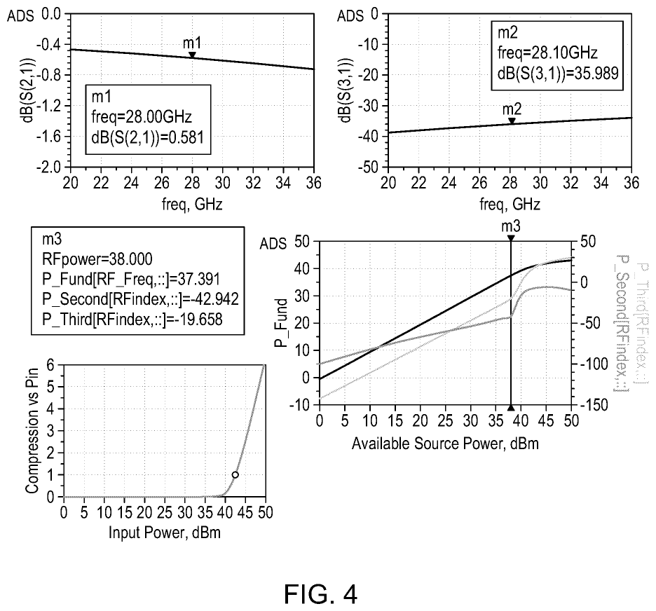

FIG. 4 shows the small and large signal plots of a SPDT switch according to an embodiment implemented using SOI, such as the switch illustrated in FIG. 2 or 3. From the plots, the switch represents about 0.6 dB insertion loss at 28 GHz, and a soft break-down around 38 dBm.

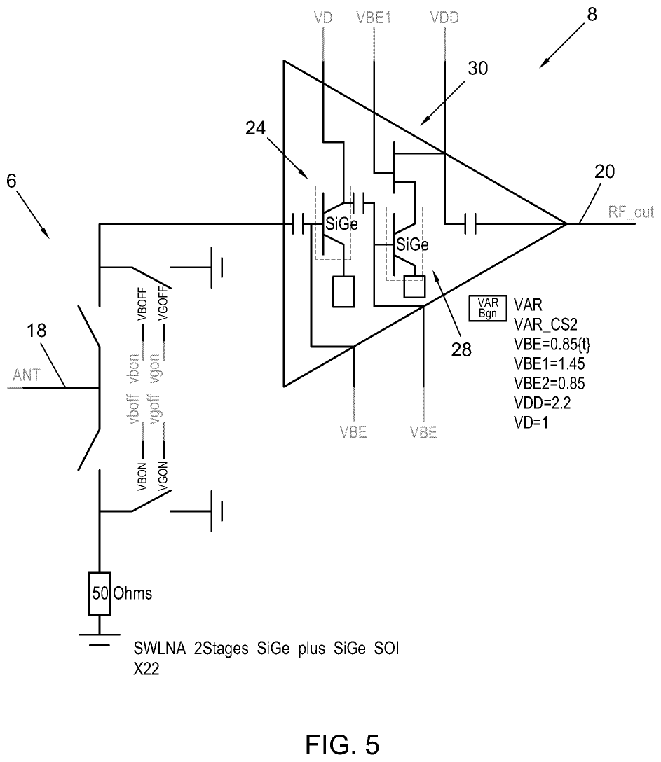

FIG. 5 shows a schematic diagram of an embodiment comprising a SOI switch 6 and LNA 8. The switch 6 is configured to connect an antenna line 18 to the LNA 8, which is configured to amplify the signal and output the amplified signal on an output line 20. The switch 6 and LNA 8 are located on the same SOI substrate. The SOI wafer comprises silicon substrate (also referred to as the handing wafer) and an active silicon layer (also referred to as the device layer) separated by a buried oxide (BOX) layer. The switch 6 comprises a plurality of transistors for switching that are formed in the active silicon layer of the SOI wafer over the BOX layer. The switch 6 also comprises a plurality of passive components (e.g. resistors) connected to the transistors that are also formed over the BOX layer to benefit from the improved isolation provided by the SOI wafer. One output of the switch 6 is directly connected to the LNA 8. The LNA 8 comprises a first amplifying stage comprising a SiGe transistor 24 formed in a bulk region of the SOI wafer, wherein the BOX layer has been removed in the bulk region and replaced with silicon. In the figures, a dashed rectangle is used to illustrate a device formed in a bulk region. Locally removing the BOX layer can improve the heat conduction from the SiGe transistor 24 as it is directly connected to the underlying silicon substrate. The second amplifying stage of the LNA 8 comprises a cascode structure having a first transistor 28 being the common emitter of the cascode structure and a second transistor 30 being the common gate of the cascode structure. The first transistor 28 is another SiGe transistor formed in a second bulk region of the SOI wafer. The SiGe transistors 24, 28 can improve the noise figure of the LNA 8, compared to a SOI transistor especially in millimeter wave frequency. The second transistor 30 of the cascode structure is a SOI transistor (e.g. as NMOS transistor) located over the BOX layer of the SOI wafer. The SOI transistor can improve the linearity of the LNA 8. The LNA 8 also comprises a plurality of passive components (e.g. capacitors and inductors), which can also benefit from the SOI wafer. The combination of the SOI SPDT switch and SOI LNA with bulk SiGe transistors can provide an improved receiver structure for a telecommunications system, such as for a UE in a 5G network.

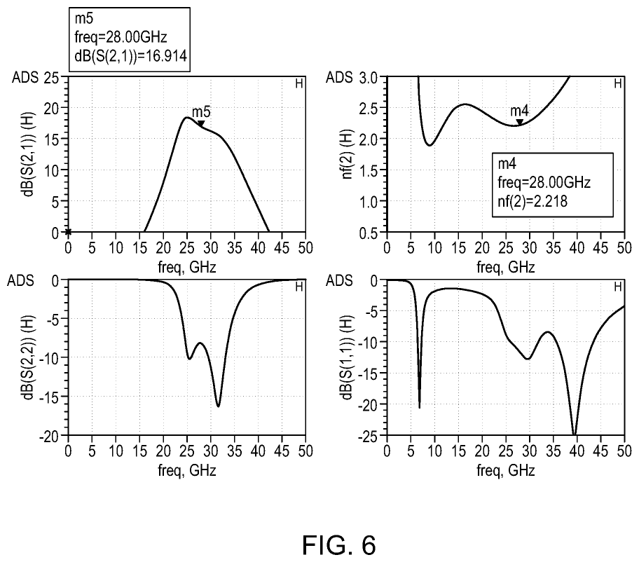

FIG. 6 shows the small signal plots from simulations of the switch and LNA system illustrated in FIG. 5. From the plots, there is sufficient gain covering the frequency range of interest of about 24 GHz to 32 GHz and an excellent noise figure (nf) around 2.2 dB at 28 GHz.

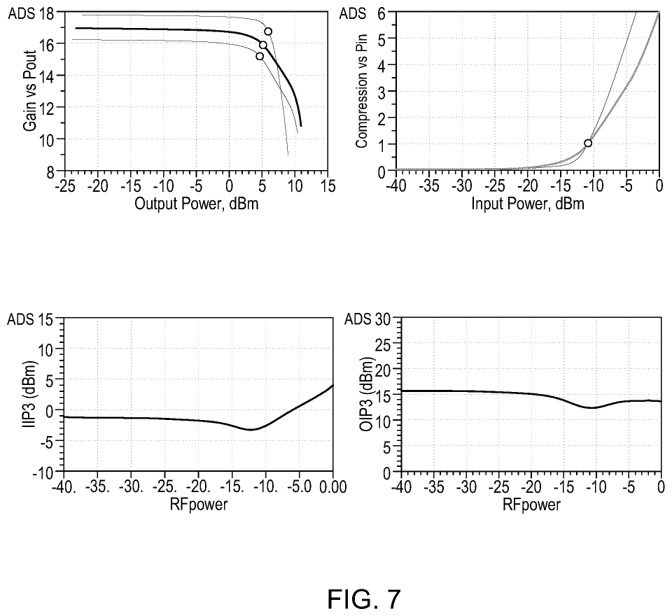

FIG. 7 shows the large signal plots from simulations of the switch and LNA system illustrated in FIG. 5. The large signal simulation shows 1 dB compression occurring at 10 dBm of input power. The large signal behavior meets the requirements for 5G systems.

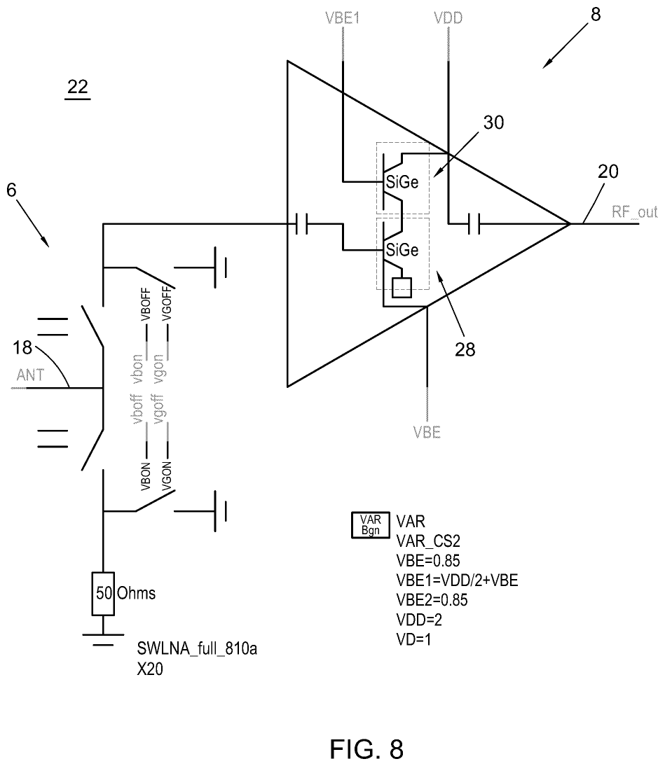

FIG. 8 shows a schematic diagram of another system according to an embodiment comprising a switch 6 and a LNA 8. The system is similar to that of FIG. 5, but the LNA 8 comprises only one amplifying stage instead of two. The LNA 8 comprises a cascode structure comprising a first transistor 28 being the common emitter and a second transistor 30 being the common base of the cascode structure. Both transistors 28, 30 are SiGe transistors formed in the bulk region(s) of the SOI wafer. The SiGe transistors can reduce the noise of the LNA 8 compared to SOI transistors.

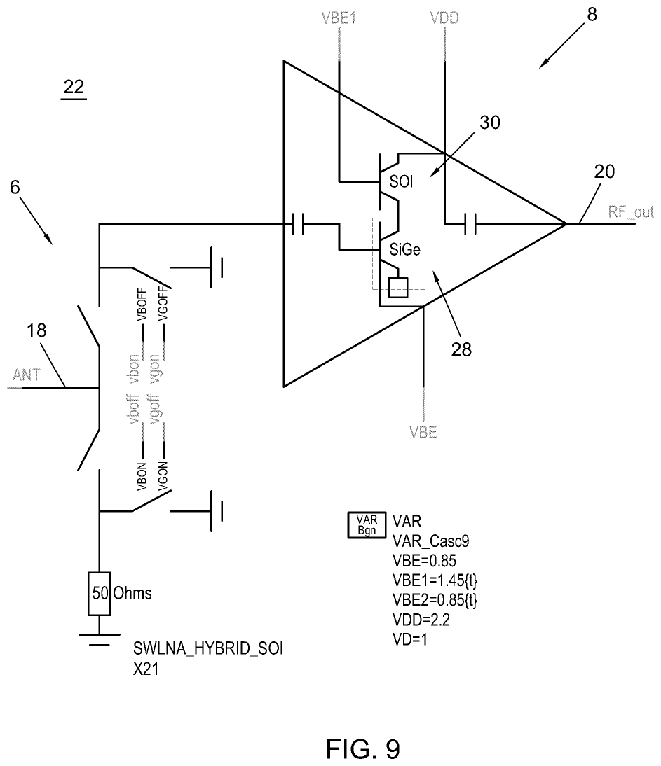

FIG. 9 shows a schematic diagram of another system according to an embodiment comprising a switch 6 and a LNA 8. The system is similar to that of FIG. 8, but instead of having two SiGe transistors in a cascode structure, the LNA 8 comprises a first transistor 28 being a SiGe transistor in a bulk region and a second transistor 30 being a SOI transistor in what is referred to herein as a hybrid cascode structure. The SiGe transistor can decrease noise while the SOI transistor may improve linearity.

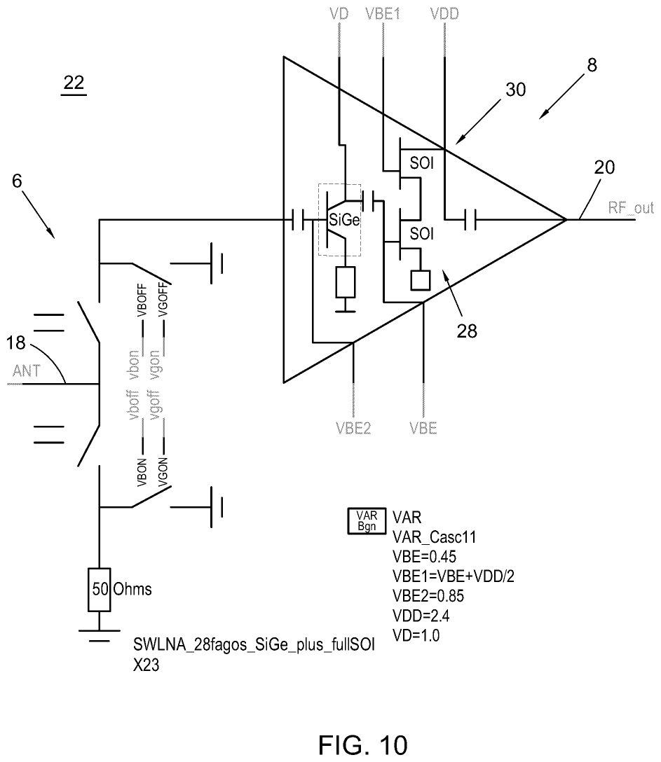

FIG. 10 shows a schematic diagram of another system according to an embodiment comprising a switch 6 and a LNA 8. The system is similar to that of FIG. 5, but instead of having a hybrid cascode structure in the second amplifying stage, the second amplifying stage comprises a cascode structure with first and second transistors 28, 32 being SOI transistors.

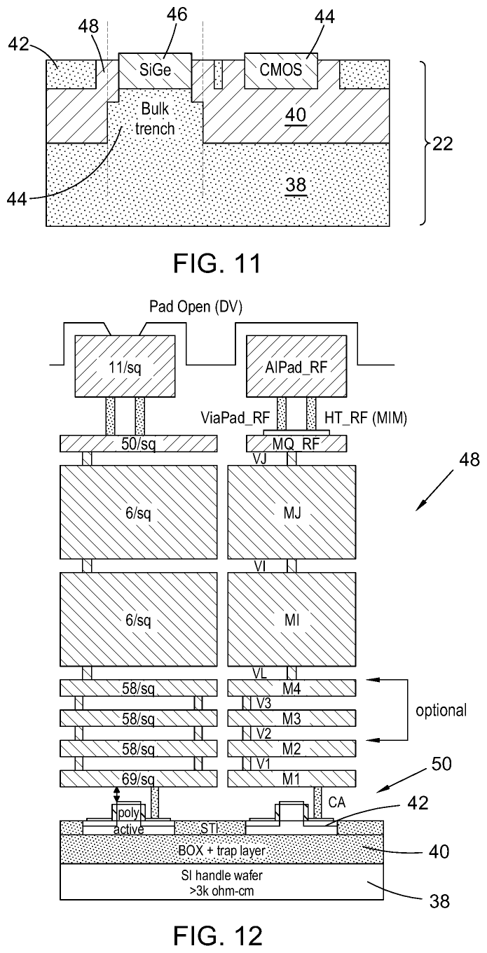

FIG. 11 shows a schematic cross section of a part of a switch LNA module such as a part of the switch or the LNA, such as the LNA 8 of FIG. 5, 8, 9 or 10. The module comprises a SOI wafer 22 comprising a silicon substrate 38, a BOX layer 40 and an active silicon layer 42. The wafer 22 also comprises a bulk region 44 filled with silicon where the BOX layer 40 has been locally removed. The LNA comprises a SiGe transistor 46 in the active silicon layer 42 in the bulk region 44.

FIG. 12 shows a schematic diagram of a part of a switch according to an embodiment. In particular, the metal layers 48 (M1 to M4, MI and MJ) on the SOI substrate connecting to SOI transistors 50 over the BOX layer 40 are illustrated. Passive components, such as inductors, may be formed from or connected by the thick top metal layers MI and MJ. The low resistivity of the thick metal layers MI, MJ can improve the performance of the passive components an reduce noise of the LNA. The thick metal layers MI, MJ can have a thickness of about 3 μm. The metal layers 51 may typically be formed in the back end of line (BEOL) of a CMOS process. The “normal” metal layers (M1 to M4) have a thickness of about 0.35 μm. The silicon substrate 38 is a HR substrate having a resistivity greater than about 3 kΩ-cm.

In general, embodiments disclosed herein provide a switch LNA module comprising a silicon on insulator (SOI) wafer comprising a silicon substrate and an active layer separated by a buried oxide (BOX) layer, a switch comprising a plurality of SOI transistors (which are formed in the SOI wafer over the BOX layer e.g. by CMOS), and a low noise amplifier (LNA) located in said SOI wafer and connected to an output of said switch, wherein said LNA comprises a bipolar transistor (e.g. a SiGe transistor) formed in a bulk region of said SOI wafer where said BOX layer is removed. Typically the switch is a series/shunts single pole double throw (SPDT) switch. The SPDT can be formed entirely in/on the SOI wafer in the active layer over the BOX layer. The SOI wafer comprises a high resistance, HR, SOI substrate comprising a silicon handle wafer having a resistivity greater than 1 kΩ-cm. The switch LNA module further comprises a thick (e.g. >2 μm thick) metal layer for connecting to the switch and LNA.

The silicon handling wafer may have a resistivity greater than 3 kΩ-cm. For example, the silicon handling wafer may have a thickness in the range of 500 μm and 1000 μm. The HR SOI substrate may reduce parasitic capacitances. The LNA may further comprise a plurality of passive components (e.g. inductors, resistors and capacitors) formed on said SOI wafer over said BOX layer. The BOX layer may, for example, have a thickness in the range of 2 μm to 4 μm. The active silicon layer typically has a thickness of less than 1 μm, for example about 0.1 μm or 0.2 μm. Devices in the active silicon layer over the BOX layer, such as transistors, are typically separated by STI.

The passive components may be formed from and/or are connected by the thick metal layer (e.g. the top metal of a CMOS backend stack) or by two at least partly overlapping thick metal layers. The thick metal layer or layers typically comprise copper. The thick metal layers may have a thickness greater than 1 μm. For example, the thick metal layers may have a thickness in the range of 2 μm to 4 μm, such as about 3 μm. The greater thickness can reduce resistance and improve the performance of at least some of the passive components. For example, inductors of the switch LNA module may be formed by one or more coil turns in the thick metal layer(s). Typically, a plurality of metal layer are located on the SOI substrate wherein the thick metal layer or layers are located at the top (furthest away from the active silicon layer). Metal 1 is the first metal layer located closest to the active silicon and may be directly connected to the bipolar transistor. The first metal layer may have a thickness of less than 1 μm, for example a thickness of about 0.3 μm, which is significantly thinner than the tick metal layer(s). The plurality of metal layers may be separated by interdielectric layers (e.g. silicon oxide layers) and be electrically connected by vias.

The LNA may comprise a cascode structure (also referred to as cascode topology) comprising said bipolar transistor being a common emitter of said cascode structure. The common base of the cascode structure can be a second bipolar transistor (e.g. a SiGe transistors) in a bulk region of the SOI wafer or a “normal” SOI transistor (e.g. CMOS transistor) formed in the active silicon layer over the BOX layer of the SOI wafer.

The LNA may comprise two amplifying stages, e.g. a first stage amplifying circuit and a second stage amplifying circuit, wherein said first stage amplifying circuit comprises said bipolar transistor and wherein said second stage amplifying circuit comprises a cascode structure. The cascode structure can comprises a first SOI transistor being a common source of said cascode structure and a second SOI transistor being a common gate of said cascode structure. In this embodiment, the second amplifying stage can comprise only SOI transistors (e.g. CMOS transistors), which may improve the linearity of the LNA. In another embodiment, said cascode structure can comprise a second bipolar transistor in a bulk region of said SOI wafer, wherein said second bipolar transistor is a common emitter of said cascode structure, and wherein the cascode structure comprises a SOI transistor being a common gate of said cascode structure. That is, the second amplifying stage comprises a hybrid cascode structure with a bipolar transistor as common emitter and a SOI transistor as common gate. The first amplifying stage typically comprises a single common emitter (no cascode structure) being the bipolar transistor in the bulk region. Alternatively, said first stage amplifying circuit can comprise a second cascode structure comprising said bipolar transistor being a common emitter of said second cascode structure. Said second cascode structure can comprises a second bipolar transistor located in a bulk region of said SOI wafer, wherein said second bipolar transistor is a common base of said cascode structure. That is, both transistors of the cascode structure of the first amplifying stage are bipolar transistors (e.g. SiGe transistors) formed in a bulk region of the SOI wafer in this embodiment. In another embodiment, said second cascode structure comprises a SOI transistor being a common gate of said cascode structure (to form a hybrid cascode structure with the bipolar transistor).

Other embodiments provide a user equipment (UE), such as a mobile phone, for telecommunications comprising a switch according to any of the described embodiments, wherein the switch is arranged in the UE to switch between a receiver mode and a transmitter mode of the UE. For example, the switch is connected to an antenna which is arranged to receive and transmit electromagnetic signals. In receiver (RX) mode, the switch connects the antenna to the LNA of the switch LNA module so that incoming signals are amplified by the LNA.

While specific embodiments of the invention have been described above, it will be apparent to one skilled in the art that modifications may be made to the invention as described without departing from the scope of the claims set out below. Each feature disclosed or illustrated in the present specification may be incorporated in the invention, whether alone or in any appropriate combination with any other feature disclosed or illustrated herein.

What is claimed is:

1. A switch LNA module comprising:
a silicon on insulator, SOL wafer comprising a silicon substrate and an active layer separated by a buried oxide, BOX, layer, wherein said SOI substrate is a high resistance, HR, SOI substrate comprising a silicon handle wafer having a resistivity greater than 1 kΩ-cm;
a switch comprising a plurality of SOI transistors;
a low noise amplifier, LNA, located in said SOI wafer and connected to an output of said switch, wherein said LNA comprises a bipolar transistor formed in a bulk region of said SOI wafer where said BOX layer is removed; and
a thick metal layer for connecting to the switch and to the LNA.

2. The switch LNA module according to claim 1, wherein said bipolar transistor is a SiGe transistor.

3. The switch LNA module according to claim 1, wherein said silicon handle wafer has a resistivity greater than 3 kΩ-cm.

4. The switch LNA module according to claim 1, further comprising a plurality of passive components formed in or on said SOI wafer over said BOX layer, wherein said passive components are formed from and/or are connected by the thick metal layer and a second, at least partly overlapping, thick metal layer.

5. The switch LNA module according to claim 1, wherein the or each thick metal layer has a thickness in the range of 2 μm to 4 μm.

6. The switch LNA module according to claim 1, wherein said LNA comprises a cascode structure comprising said bipolar transistor being a common emitter of said cascode structure.

7. The switch LNA module according to claim 6, wherein said LNA comprises a second bipolar transistor being a common base of said cascode structure.

8. The switch LNA module according to claim 6, further comprising a SOI transistor, wherein said cascode structure comprises said SOI transistor being a common gate of said cascode structure.

9. The switch LNA module according to claim 8, wherein said SOI transistor is a complementary metal-oxide semiconductor (CMOS) transistor.

10. The switch LNA module according to claim 1, and comprising a first stage amplifying circuit and a second stage amplifying circuit, wherein said first stage amplifying circuit comprises said bipolar transistor and wherein said second stage amplifying circuit comprises a cascode structure.

11. The switch LNA module according to claim 10, wherein said cascode structure comprises a first SOI transistor being a common source of said cascode structure and a second SOI transistor being a common gate of said cascode structure.

12. The switch LNA module according to claim 10, wherein said cascode structure comprises a second bipolar transistor in a bulk region of said SOI wafer, wherein said second bipolar transistor is a common emitter of said cascode structure, and a SOI transistor being a common gate of said cascode structure.

13. The switch LNA module according to claim 10, wherein said first stage amplifying circuit comprises a second cascode structure comprising said bipolar transistor being a common emitter of said second cascode structure.

14. The switch LNA module according to claim 13, wherein said second cascode structure comprises a second bipolar transistor located in a bulk region of said SOI wafer, wherein said second bipolar transistor is a common base of said cascode structure.

15. The switch LNA module according to claim 13, wherein said second cascode structure comprises a SOI transistor being a common gate of said cascode structure.

16. An apparatus for telecommunications comprising the switch LNA module according to claim 1, wherein the switch of the switch LNA module is arranged in said apparatus to switch between a receiver mode and a transmitter mode of said apparatus.
